(19) United States
(12) Patent Application Publication
(10) Pub. No.: US 2025/0246566 A1
(43) Pub. Date: Jul. 31, 2025

(54) Device Excluding a Semiconductor Chip Having Symmetrical Interconnects

(71) Applicant: Taiwan Semiconductor Manufacturing Company, Ltd., Hsinchu (TW)

(72) Inventor: Shenggao Li, Hsinchu (TW)

(21) Appl. No.: 18/768,508

(22) Filed: Jul. 10, 2024

Related U.S. Application Data
(60) Provisional application No. 63/625,010, filed on Jan. 25, 2024.

(51) Int. Cl. H01L 23/00; H01L 23/538; H01L 25/00; H01L 25/065

(52) U.S. Cl. CPC H01L 24/06; H01L 24/14; H01L 24/16; H01L 24/17; H01L 25/0652; H01L 25/50; H01L 23/5383; H01L 2224/06151; H01L 2224/06181; H01L 2224/06515; H01L 2224/14151; H01L 2224/14181; H01L 2224/16145; H01L 2224/16225; H01L 2224/17515

(57) ABSTRACT

A device includes a plurality of semiconductor chips stacked on top of each other. A semiconductor includes a substrate, a device layer, a conductive layer, a chip node, and a plurality of interconnects. The device layer is formed on the substrate and includes a plurality of chip components. The conductive layer interconnects the chip components. The chip node is connected to the conductive layer and associated with a distinct signal. The interconnects are formed on a surface of the semiconductor chip, are connected to the chip node, and are arranged symmetrically with respect to an x-axis or a y-axis. A method for manufacturing the device is also disclosed.

### CROSS-REFERENCE TO RELATED APPLICATION

The present application claims priority to U.S. Provisional Application No. 63/625,010, filed Jan. 25, 2024, the contents of which are incorporated by reference herein in its entirety.

### BACKGROUND

Packaging technologies, such as three-dimensional integrated circuit (3D-IC) and chip-on-wafer-on-substrate (CoWoS) technologies, involve stacking semiconductor chips (also referred to as integrated circuits or dies) on top of each other to enhance performance while reducing footprint. A semiconductor chip may take a wide variety of forms. In one example, a chip comprises a chip substrate, chip components (e.g., passive electronic components, such as resistors, capacitors, and inductors, as well as active electronic components, such as transistors) formed on the chip substrate, a conductive layer that interconnects the chip components, and interconnects formed on a bottom surface and/or a top surface of the conductive layer.

### BRIEF DESCRIPTION OF THE DRAWINGS

Aspects of the present disclosure are best understood from the following detailed description when read with the accompanying figures:

FIG. 1 is a sectional view illustrating an exemplary device 100 in accordance with various embodiments of the present disclosure;

FIG. 2 is a bottom (or top) view illustrating exemplary interconnects of a semiconductor chip in accordance with various embodiments of the present disclosure;

FIG. 3 is a bottom (or top) view illustrating another exemplary interconnects of a semiconductor chip in accordance with various embodiments of the present disclosure;

FIG. 4 is a bottom (or top) view illustrating another exemplary interconnects of a semiconductor chip in accordance with various embodiments of the present disclosure;

FIG. 5 is a bottom (or top) view illustrating another exemplary interconnects of a semiconductor chip in accordance with various embodiments of the present disclosure;

FIG. 6 is a bottom (or top) view illustrating another exemplary interconnects of a semiconductor chip in accordance with various embodiments of the present disclosure;

FIG. 7 is a bottom (or top) view illustrating another exemplary interconnects of a semiconductor chip in accordance with various embodiments of the present disclosure;

FIG. 8 is a bottom (or top) view illustrating another exemplary interconnects of a semiconductor chip 130 in accordance with various embodiments of the present disclosure;

FIG. 9 is a bottom (or top) view illustrating another exemplary interconnects of a semiconductor chip in accordance with various embodiments of the present disclosure;

FIG. 10 is a bottom (or top) view illustrating another exemplary interconnects of a semiconductor chip in accordance with various embodiments of the present disclosure; and

FIG. 11 is a flowchart of an exemplary method for manufacturing a device in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Packaging technologies, such as three-dimensional integrated circuit (3D-IC) and chip-on-wafer-on-substrate (CoWoS) technologies, involve stacking semiconductor chips (also referred to as integrated circuits or dies) on top of each other to enhance performance while reducing footprint. A semiconductor chip may take a wide variety of forms. In one example, a semiconductor chip includes a chip substrate, chip components (e.g., passive electronic components, such as resistors, capacitors, and inductors, as well as active electronic components, such as transistors) formed on the chip substrate, a conductive layer that interconnects the chip components, and interconnects formed on a bottom surface and/or a top surface of the conductive layer.

The interconnects are used in semiconductor packaging to create an electrical connection between stacked semiconductor chips or between a semiconductor chip and an interposer or a substrate and can be in the form of micro-bumps, solder balls, copper pillars, a combination of metal and dielectric interconnects, other interconnects created by, e.g., hybrid bonding, tape-automated bonding (TAB), wire bonding, flip-chip bonding, other suitable interconnects, or combinations thereof. For example, an electrical connection between a pair of semiconductor chips of a package may be established by aligning interconnects of one of the semiconductor chips with nodes on the other of the semiconductor chips. The interconnects are then bonded to the nodes using a solder reflow process. Next, an insulating material is applied to underfill the gap between the interconnects and the semiconductor chips and to provide a stronger mechanical connection between the semiconductor chips. Thereafter, the package undergoes a cooling stage to solidify the solder joints, forming a permanent and reliable electrical connection between the semiconductor chips.

In certain examples, during a manufacturing of a device with such packaging technologies, semiconductor chips of the device are oriented or aligned relative to each other to ensure correct bonding to each other using interconnects. This step of a manufacturing process can be prone to errors. If a misalignment between the semiconductor chips occurs, interconnects, which are connected to a node that, e.g., receives a supply voltage, of one of the semiconductor chips may be inadvertently connected to, e.g., an electrical ground node of the other of the semiconductor chips, causing electrical shorts in the device. Systems and methods as described in certain examples herein mitigate this shortcoming by arranging interconnects of a semiconductor chip symmetrically with respect to an x-axis, a y-axis, or both. This ensures correct bonding of the semiconductor chip to a substrate, interposer, or another semiconductor chip regardless of the orientation of the semiconductor chip, in a manner that will be described in detail hereinafter.

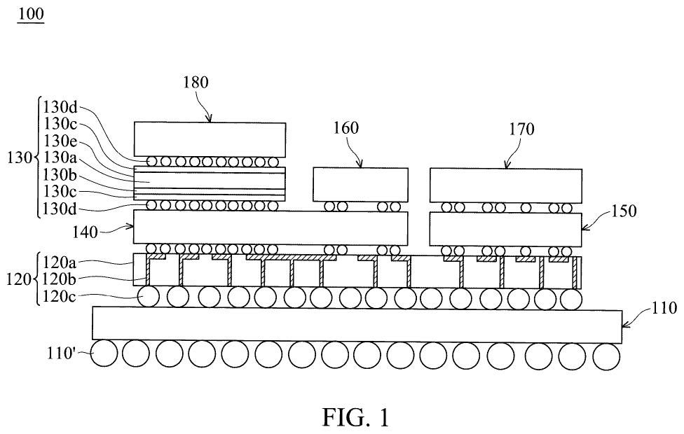

FIG. 1 is a sectional view illustrating an exemplary device 100 in accordance with various embodiments of the present disclosure. As illustrated in FIG. 1, the example device 100, e.g., a semiconductor package (such as a 3D-IC or CoWos package), includes a package substrate 110, an interposer 120, and a plurality of semiconductor chips 130-180. The package substrate 110 may be formed with conductive horizontal lines (or interconnects) therein, conductive vertical lines (or vias) therein, and/or through-silicon vias (TSVs) therethrough and conductive bumps 110′ on a bottom surface thereof. Examples of materials for the package substrate 110 include silicon, germanium, III-V semiconductor materials, other suitable semiconductor material, and an alloy thereof. The conductive horizontal and vertical lines, TSVs, and the conductive bumps 110′ may be made from copper, aluminum, nickel, barrier metals (e.g., titanium, tungsten, and tantalum), gold, tin, other suitable conductive material, or an alloy thereof. In certain embodiments, the device 100 is dispensed with the package substrate 110.

The interposer 120 is mounted on the package substrate 110 and includes an interposer substrate 120a, a redistribution layer (RDL) 120b formed in the interposer substrate 120a, and interconnect bumps 120c formed on a bottom surface of the interposer substrate 120a. The interposer 120 may further include conductive horizontal lines (or interconnects), conductive vertical lines (or vias), and/or TSVs embedded in the interposer substrate 120a. Examples of materials for the interposer substrate 120a may be made from silicon, germanium, III-V semiconductor materials, other suitable semiconductor material, and an alloy thereof. The RDL 120b, the conductive horizontal and vertical lines, the TSVs, and the interconnect bumps 120c may be made from copper, aluminum, nickel, barrier metals (e.g., titanium, tungsten, and tantalum), gold, tin, other suitable conductive material, or an alloy thereof.

The semiconductor chip 130 includes a chip substrate 130a, a device layer 130b, a conductive layer 130c, and a plurality of interconnects 130d. Examples of materials for the chip substrate 130a include silicon, germanium, III-V semiconductor materials, other suitable semiconductor material, and an alloy thereof. The device layer 130b is formed on the bottom surface of the chip substrate 130a and includes a plurality of chip components (e.g., passive electronic components, such as resistors, capacitors, and inductors, as well as active electronic components, such as transistors). The conductive layer 130c is formed over the chip substrate 130a and over the device layer 130b, interconnects the chip components of the device layer 130b, and includes conductive horizontal lines (or interconnects) and conductive vertical lines (or vias). The interconnects 130d are formed on the top and bottom surfaces of the conductive layer 130c. The conductive layer 130c and the interconnects 130d may be made from copper, aluminum, nickel, barrier metals (e.g., titanium, tungsten, and tantalum), gold, tin, other suitable conductive material, or an alloy thereof.

The semiconductor chip 130 further includes an encapsulant 130e that covers the chip substrate 130a, the device layer 130b, and the conductive layer 130c and protects the semiconductor chip 130 from the external environment. Examples of materials for the encapsulant 130e include epoxy mold compounds (EMC), silicone, and polyurethanes. The semiconductor chip 140 is between a portion of the interposer 120 and the semiconductor chip 130. The semiconductor chip 150 is mounted on another portion of the interposer 120. The semiconductor chip 160 is bonded to the top surface of the semiconductor chip 140. The semiconductor chip 170 is bonded to the semiconductor chip 150. The semiconductor chip 180 is stacked on the top surface of the semiconductor chip 130.

Although the device 100 is exemplified as a 3D-IC or CoWos package, it should be understood that, after reading this disclosure, the device 100 may be fabricated using other suitable semiconductor packaging technologies.

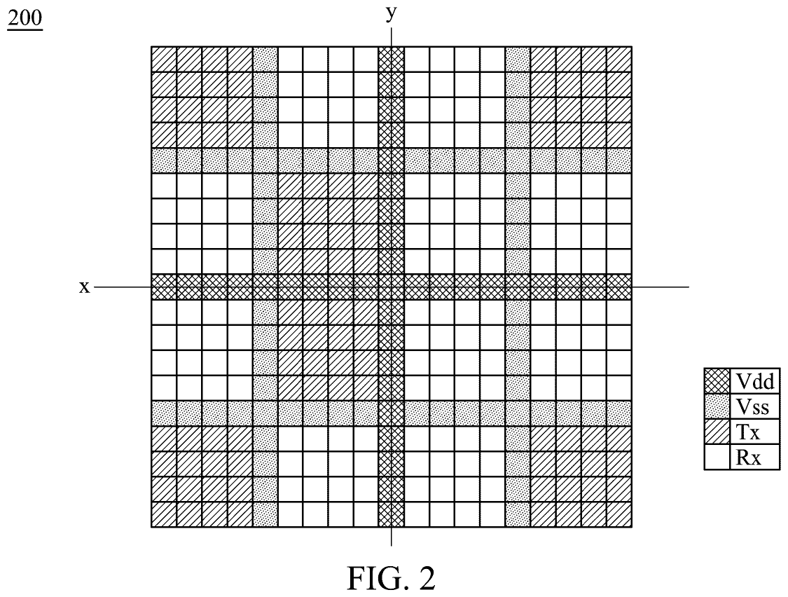

FIG. 2 is a bottom (or top) view illustrating exemplary interconnects 200 of the semiconductor chip 130 in accordance with various embodiments of the present disclosure. As illustrated in FIG. 2, the example interconnects 200 include supply voltage (Vdd) interconnects, supply voltage (Vss) interconnects, transmitter (Tx) interconnects, and receiver (Rx) interconnects. In this exemplary embodiment, the semiconductor chip 130 further includes a plurality of chip nodes connected to the conductive layer 130c. The chip nodes include a supply voltage (Vdd) node that receives a supply voltage (Vdd) signal, a supply voltage (Vss) node that receives a supply voltage (Vss) signal, a plurality of transmitter (Tx) nodes, each of which transmits a respective one of a plurality of signals (e.g., data signals), and a plurality of receiver (Rx) nodes, each of which receives a respective one of a plurality of signals (e.g., data signals).

With reference to FIG. 2, the supply voltage (Vdd) interconnects are connected to the supply voltage (Vdd) node and lie along the x- and y-axes. In this exemplary embodiment, the supply voltage (Vdd) interconnects are symmetrical with respect to the x- and y-axes. For example, the number of the supply voltage (Vdd) interconnects on one side of the x-axis is the same as the number of the supply voltage (Vdd) interconnects on the other side of the x-axis and their positions mirror each other relative to the x-axis. Similarly, the number of the supply voltage (Vdd) interconnects on one side of the y-axis is the same as the number of the supply voltage (Vdd) interconnects on the other side of the y-axis and their positions mirror each other relative to the y-axis. In certain embodiments, the supply voltage (Vdd) interconnects are arranged on opposite sides of the x- and y-axes.

In an alternative embodiment, the supply voltage (Vdd) interconnects are asymmetrical with respect to the y-axis. For example, the number of the supply voltage (Vdd) interconnects on one side of the y-axis is greater or less than the number of the supply voltage (Vdd) interconnects on the other side of the y-axis. As another example, the number of the supply voltage (Vdd) interconnects on one side of the y-axis is the same as the number of the supply voltage (Vdd) interconnects on the other side of the y-axis. In such another example, the positions of the supply voltage (Vdd) interconnects do not form a mirror image with respect to the y-axis.

Similarly, the supply voltage (Vss) interconnects are connected to the supply voltage (Vss) node and are arranged on opposite sides of the x- and y-axes. In this exemplary embodiment, the supply voltage (Vss) interconnects are symmetrical with respect to the x- and y-axes. For example, the number of the supply voltage (Vss) interconnects on one side of the x-axis is the same as the number of the supply voltage (Vss) interconnects on the other side of the x-axis and their positions mirror each other relative to the x-axis. Similarly, the number of the supply voltage (Vss) interconnects on one side of the y-axis is the same as the number of the supply voltage (Vss) interconnects on the other side of the y-axis and their positions mirror each other relative to the y-axis.

In an alternative embodiment, the supply voltage (Vss) interconnects are asymmetrical with respect to the y-axis. For example, the number of the supply voltage (Vss) interconnects on one side of the y-axis is greater or less than the number of the supply voltage (Vss) interconnects on the other side of the y-axis. As another example, the number of the supply voltage (Vss) interconnects on one side of the y-axis is the same as the number of the supply voltage (Vss) interconnects on the other side of the y-axis. In such another example, the positions of the supply voltage (Vss) interconnects do not form a mirror image with respect to the y-axis.

The transmitter (Tx) interconnects, e.g., a certain number of which, are connected to a specific transmitter (Tx) node and are arranged on opposite sides of the x- and y-axes. In this exemplary embodiment, the transmitter (Tx) interconnects are symmetrical with respect to the x-axis. For example, the number of the transmitter (Tx) interconnects on one side of the x-axis is the same as the number of the transmitter (Tx) interconnects on the other side of the x-axis and their positions mirror each other relative to the x-axis.

As further illustrated in FIG. 2, the transmitter (Tx) interconnects are asymmetrical with respect to the y-axis. For example, the number of the transmitter (Tx) interconnects on one side of the y-axis is greater or less than the number of the transmitter (Tx) interconnects on the other side of the y-axis. As another example, the number of the transmitter (Tx) interconnects on one side of the y-axis is the same as the number of the transmitter (Tx) interconnects on the other side of the y-axis. In such another example, the positions of the transmitter (Tx) interconnects do not form a mirror image with respect to the y-axis.

Similarly, the receiver (Rx) interconnects, e.g., a certain number of which, are connected to a specific receiver (Rx) node and are arranged on opposite sides of the x- and y-axes. In this exemplary embodiment, the receiver (Rx) interconnects are symmetrical with respect to the x-axis. For example, the number of the receiver (Rx) interconnects on one side of the x-axis is the same as the number of the receiver (Rx) interconnects on the other side of the x-axis and their positions mirror each other relative to the x-axis.

As further illustrated in FIG. 2, the receiver (Rx) interconnects are asymmetrical with respect to the y-axis. For example, the number of the receiver (Rx) interconnects on one side of the y-axis is greater or less than the number of the receiver (Rx) interconnects on the other side of the y-axis. As another example, the number of the receiver (Rx) interconnects on one side of the y-axis is the same as the number of the receiver (Rx) interconnects on the other side of the y-axis. In such another example, the positions of the receiver (Rx) interconnects do not form a mirror image with respect to the y-axis.

From the above description, the semiconductor chip 130 includes interconnects 200 on top and bottom surfaces thereof. The interconnects 200 on the top surface of the semiconductor chip 130 are symmetrical with respect to the x-axis, as are the interconnects 200 on the bottom surface of the semiconductor chip 130. The construction as such ensures correct bonding of the semiconductor chip 130 on another semiconductor chip, e.g., the semiconductor chip 140, or an interposer, e.g., interposer 120, even when the semiconductor chip 130 is rotated by 180° about the x-axis.

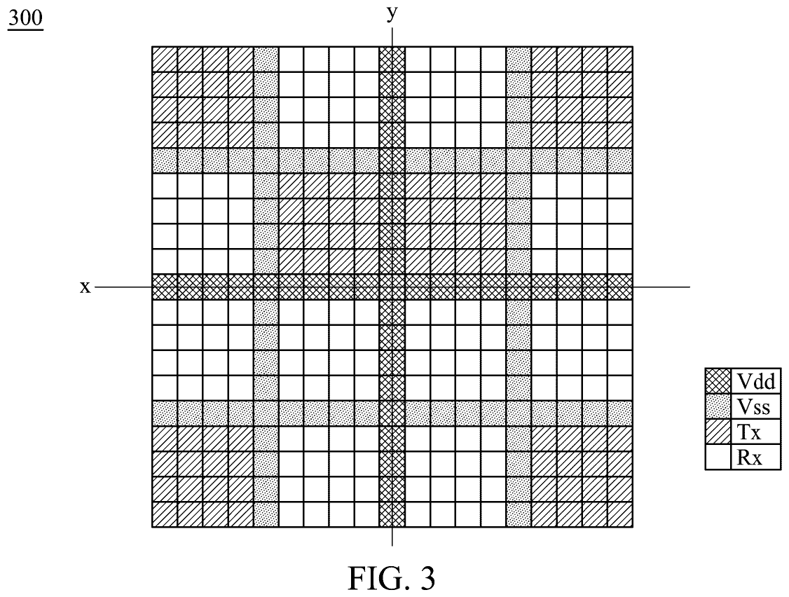

FIG. 3 is a bottom (or top) view illustrating another exemplary interconnects 300 of the semiconductor chip 130 in accordance with various embodiments of the present disclosure. As illustrated in FIG. 3, the example interconnects 300 differ from the interconnects 200 in that the transmitter (Tx) interconnects are symmetrical with respect to the y-axis. For example, the number of the transmitter (Tx) interconnects on one side of the y-axis is the same as the number of the transmitter (Tx) interconnects on the other side of the y-axis and their positions mirror each other relative to the y-axis.

As further illustrated in FIG. 3, the transmitter (Tx) interconnects are asymmetrical with respect to the x-axis. For example, the number of the transmitter (Tx) interconnects on one side of the x-axis is greater or less than the number of the transmitter (Tx) interconnects on the other side of the x-axis. As another example, the number of the transmitter (Tx) interconnects on one side of the x-axis is the same as the number of the transmitter (Tx) interconnects on the other side of the x-axis. In such another example, the positions of the transmitter (Tx) interconnects do not form a mirror image with respect to the x-axis.

Similarly, the receiver (Rx) interconnects are symmetrical with respect to the y-axis. For example, the number of the receiver (Rx) interconnects on one side of the y-axis is the same as the number of the receiver (Rx) interconnects on the other side of the y-axis and their positions mirror each other relative to the y-axis.

As further illustrated in FIG. 3, the receiver (Rx) interconnects are asymmetrical with respect to the x-axis. For example, the number of the receiver (Rx) interconnects on one side of the x-axis is greater or less than the number of the receiver (Rx) interconnects on the other side of the x-axis. As another example, the number of the receiver (Rx) interconnects on one side of the x-axis is the same as the number of the receiver (Rx) interconnects on the other side of the x-axis. In such another example, the positions of the receiver (Rx) interconnects do not form a mirror image with respect to the x-axis.

From the above description, the semiconductor chip 130 includes interconnects 300 on top and bottom surfaces thereof. The interconnects 300 on the top surface of the semiconductor chip 130 are symmetrical with respect to the y-axis, as are the interconnects 300 on the bottom surface of the semiconductor chip 130. The construction as such ensures correct bonding of the semiconductor chip 130 on another semiconductor chip, e.g., the semiconductor chip 140, or an interposer, e.g., interposer 120, even when the semiconductor chip 130 is rotated by 180° about the y-axis.

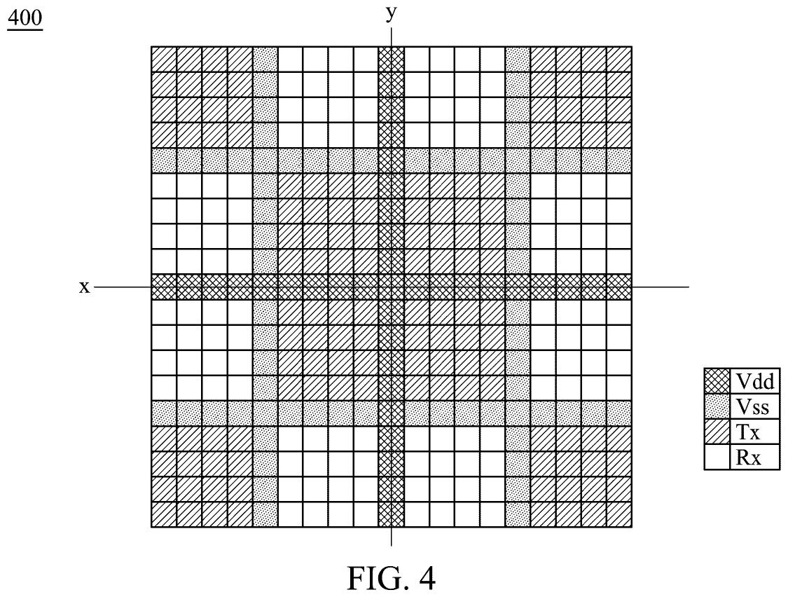

FIG. 4 is a bottom (or top) view illustrating another exemplary interconnects 400 of the semiconductor chip 130 in accordance with various embodiments of the present disclosure. As illustrated in FIG. 4, the example interconnects 400 differ from the interconnects 200, 300 in that the transmitter (Tx) interconnects are symmetrical with respect to the x- and y-axes. For example, the number of the transmitter (Tx) interconnects on one side of the x-axis is the same as the number of the transmitter (Tx) interconnects on the other side of the x-axis and their positions mirror each other relative to the x-axis. Similarly, the number of the transmitter (Tx) interconnects on one side of the y-axis is the same as the number of the transmitter (Tx) interconnects on the other side of the y-axis and their positions mirror each other relative to the x-axis.

The receiver (Rx) interconnects are symmetrical with respect to the x- and y-axes. For example, the number of the receiver (Rx) interconnects on one side of the x-axis is the same as the number of the receiver (Rx) interconnects on the other side of the x-axis and their positions mirror each other relative to the x-axis. Similarly, the number of the receiver (Rx) interconnects on one side of the y-axis is the same as the number of the receiver (Rx) interconnects on the other side of the y-axis and their positions mirror each other relative to the y-axis.

From the above description, the semiconductor chip 130 includes interconnects 400 on top and bottom surfaces thereof. The interconnects 400 on the top surface of the semiconductor chip 130 are symmetrical with respect to the x- and y-axes, as are the interconnects 400 on the bottom surface of the semiconductor chip 130. The construction as such ensures correct bonding of the semiconductor chip 130 on another semiconductor chip, e.g., the semiconductor chip 140, or an interposer, e.g., interposer 120, even when the semiconductor chip 130 is rotated by 180° about the x- or y-axis or by 90°, 180°, or 270° about an axis transverse to the x- and y-axes.

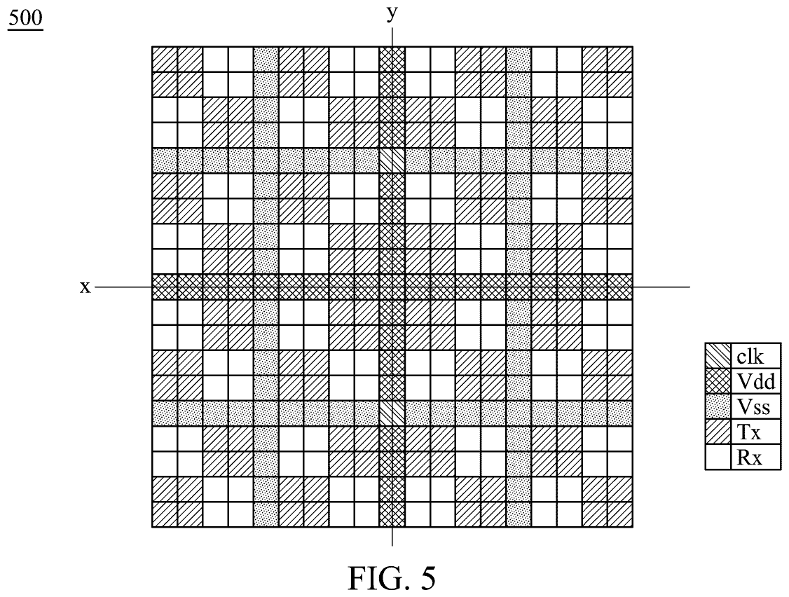

FIG. 5 is a bottom (or top) view illustrating another exemplary interconnects 500 of the semiconductor chip 130 in accordance with various embodiments of the present disclosure. As illustrated in FIG. 5, the example interconnects 500 differ from the interconnects 200-400 in that the interconnects 500 further include clock (clk) interconnects. The chip nodes further includes a clock (clk) node that transmits or receives a clock signal. The clock (clk) interconnects are connected to the clock (clk) node and lie with respect to the y-axis. In this exemplary embodiment, the clock (clk) interconnects are symmetrical with respect to the x-axis. For example, the number of the clock (clk) interconnects on one side of the x-axis is the same as the number of the clock (clk) interconnects on the other side of the x-axis and their positions mirror each other relative to the x-axis.

In an alternative embodiment, the interconnects 500 further include second clock (clk) interconnects that are connected to the clock (clk) node and that lie with respect to the x-axis. In such an alternative embodiment, the second clock (clk) interconnects are asymmetrical with respect to the y-axis. For example, the number of the second clock (clk) interconnects on one side of the y-axis is greater or less than the number of the second clock (clk) interconnects on the other side of the y-axis. As another example, the number of the second clock (clk) interconnects on one side of the y-axis is the same as the number of the second clock (clk) interconnects on the other side of the y-axis. In such another example, the positions of the second clock (clk) interconnects do not form a mirror image with respect to the y-axis.

Because multiple interconnects are connected to a clock node, a clock signal is more evenly distributed, reducing or eliminating, time differences (skew) between different points of the device 100 receiving the same clock signal.

From the above description, the semiconductor chip 130 includes interconnects 500 on top and bottom surfaces thereof. The interconnects 500 on the top surface of the semiconductor chip 130 are symmetrical with respect to the x-axis, as are the interconnects 500 on the bottom surface of the semiconductor chip 130. The construction as such ensures correct bonding of the semiconductor chip 130 on another semiconductor chip, e.g., the semiconductor chip 140, or an interposer, e.g., interposer 120, even when the semiconductor chip 130 is rotated by 180° about the x-axis.

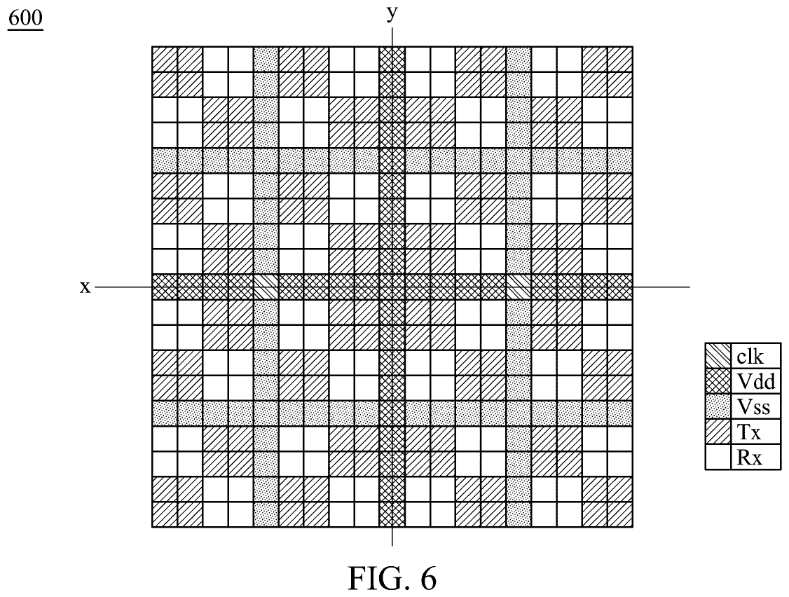

FIG. 6 is a bottom (or top) view illustrating another exemplary interconnects 600 of the semiconductor chip 130 in accordance with various embodiments of the present disclosure. As illustrated in FIG. 6, the example interconnects 600 differ from the interconnects 200-400 in that the interconnects 600 further include clock (clk) interconnects. The chip nodes further includes a clock (clk) node that transmits or receives a clock signal. The clock (clk) interconnects are connected to the clock (clk) node and lie with respect to the x-axis. In this exemplary embodiment, the clock (clk) interconnects are symmetrical with respect to the y-axis. For example, the number of the clock (clk) interconnects on one side of the y-axis is the same as the number of the clock (clk) interconnects on the other side of the y-axis and their positions mirror each other relative to the y-axis.

In an alternative embodiment, the interconnects 600 further include second clock (clk) interconnects that are connected to the clock (clk) node and that lie with respect to the y-axis. In such an alternative embodiment, the second clock (clk) interconnects are asymmetrical with respect to the x-axis. For example, the number of the second clock (clk) interconnects on one side of the x-axis is greater or less than the number of the second clock (clk) interconnects on the other side of the x-axis. As another example, the number of the second clock (clk) interconnects on one side of the x-axis is the same as the number of the second clock (clk) interconnects on the other side of the x-axis. In such another example, the positions of the second clock (clk) interconnects do not form a mirror image with respect to the x-axis.

From the above description, the semiconductor chip 130 includes interconnects 600 on top and bottom surfaces thereof. The interconnects 600 on the top surface of the semiconductor chip 130 are symmetrical with respect to the y-axis, as are the interconnects 500 on the bottom surface of the semiconductor chip 130. The construction as such ensures correct bonding of the semiconductor chip 130 on another semiconductor chip, e.g., the semiconductor chip 140, or an interposer, e.g., interposer 120, even when the semiconductor chip 130 is rotated by 180° about the y-axis.

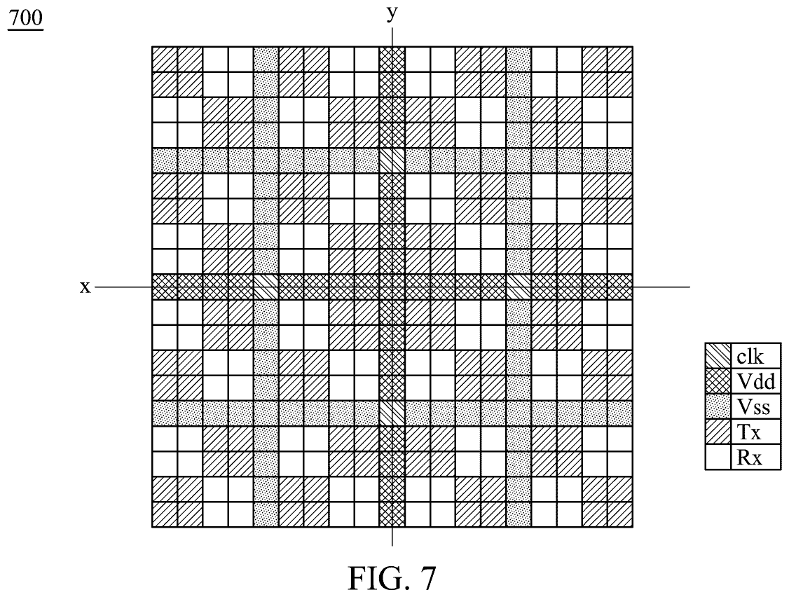

FIG. 7 is a bottom (or top) view illustrating another exemplary interconnects 700 of the semiconductor chip 130 in accordance with various embodiments of the present disclosure. As illustrated in FIG. 7, the example interconnects 700 differ from the interconnects 200-400 in that the interconnects 700 further include clock (clk) interconnects. The chip nodes further includes a clock (clk) node that transmits or receives a clock signal. The clock (clk) interconnects are connected to the clock (clk) node and lie along the x- and y-axes. In this exemplary embodiment, the clock (clk) interconnects are symmetrical with respect to the x- and y-axes. For example, the number of the clock (clk) interconnects on one side of the x-axis is the same as the number of the clock (clk) interconnects on the other side of the x-axis and their positions mirror each other relative to the y-axis. Similarly, the number of the clock (clk) interconnects on one side of the y-axis is the same as the number of the clock (clk) interconnects on the other side of the y-axis and their positions mirror each other relative to the y-axis.

From the above description, the semiconductor chip 130 includes interconnects 700 on top and bottom surfaces thereof. The interconnects 700 on the top surface of the semiconductor chip 130 are symmetrical with respect to the x- and y-axes, as are the interconnects 700 on the bottom surface of the semiconductor chip 130. The construction as such ensures correct bonding of the semiconductor chip 130 on another semiconductor chip, e.g., the semiconductor chip 140, or an interposer, e.g., interposer 120, even when the semiconductor chip 130 is rotated by 180° about the x- or y-axis or by 90°, 180°, or 270° about an axis transverse to the x- and y-axes.

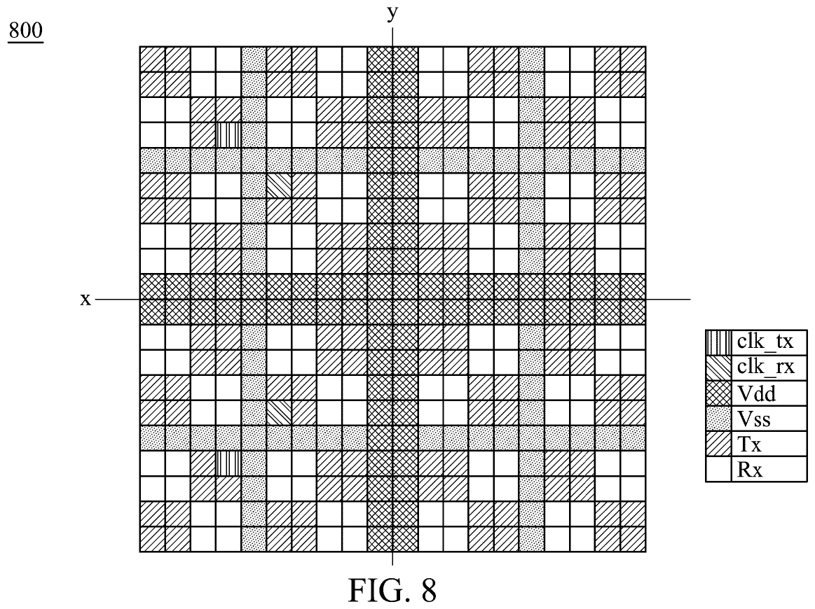

FIG. 8 is a bottom (or top) view illustrating another exemplary interconnects 800 of the semiconductor chip 130 in accordance with various embodiments of the present disclosure. As illustrated in FIG. 8, the example interconnects 800 differ from the interconnects 200-400 in that the interconnects 800 further include transmitter clock (clk_tx) interconnects and receiver clock (clk_rx) interconnects. The chip nodes further includes a transmitter clock (clk_tx) node that transmits a first clock signal and a receiver clock (clk_rx) node that receives a second clock signal. The transmitter clock (clk_tx) interconnects are connected to the transmitter clock (clk_tx) node and are arranged on opposite sides of the x-axis. In this exemplary embodiment, the transmitter clock (clk_tx) interconnects are symmetrical with respect to the x-axis. For example, the number of the transmitter clock (clk_tx) interconnects on one side of the x-axis is the same as the number of the transmitter clock (clk_tx) interconnects on the other side of the x-axis and their positions mirror each other relative to the x-axis.

In an alternative embodiment, the interconnects 800 further include second transmitter clock (clk_tx) interconnects arranged on opposite sides of the y-axis. In such an alternative embodiment, the second transmitter clock (clk_tx) interconnects are asymmetrical with respect to the y-axis. For example, the number of the second transmitter clock (clk_tx) interconnects on one side of the y-axis is greater or less than the number of the second transmitter clock (clk_tx) interconnects on the other side of the y-axis. As another example, the number of the second transmitter clock (clk_tx) interconnects on one side of the y-axis is the same as the number of the second transmitter clock (clk_tx) interconnects on the other side of the y-axis. In such another example, the positions of the transmitter clock (clk_tx) interconnects do not form a mirror image with respect to the y-axis.

Similarly, the receiver clock (clk_rx) interconnects are connected to the receiver clock (clk_rx) node and are arranged on opposite sides of the x-axis. In this exemplary embodiment, the receiver clock (clk_rx) interconnects are symmetrical with respect to the x-axis. For example, the number of the receiver clock (clk_rx) interconnects on one side of the x-axis is the same as the number of the receiver clock (clk_rx) interconnects on the other side of the x-axis and their positions mirror each other relative to the x-axis.

In an alternative embodiment, the interconnects 800 further include second receiver clock (clk_rx) interconnects arranged on opposite sides of the y-axis. In such an alternative embodiment, the second receiver clock (clk_rx) interconnects are asymmetrical with respect to the y-axis. For example, the number of the second receiver clock (clk_rx) interconnects on one side of the y-axis is greater or less than the number of the second receiver clock (clk_rx) interconnects on the other side of the y-axis. As another example, the number of the second receiver clock (clk_rx) interconnects on one side of the y-axis is the same as the number of the second receiver clock (clk_rx) interconnects on the other side of the y-axis. In such another example, the positions of the second receiver clock (clk_rx) interconnects do not form a mirror image with respect to the y-axis.

From the above description, the semiconductor chip 130 includes interconnects 800 on top and bottom surfaces thereof. The interconnects 800 on the top surface of the semiconductor chip 130 are symmetrical with respect to the x-axis, as are the interconnects 800 on the bottom surface of the semiconductor chip 130. The construction as such ensures correct bonding of the semiconductor chip 130 on another semiconductor chip, e.g., the semiconductor chip 140, or an interposer, e.g., interposer 120, even when the semiconductor chip 130 is rotated by 180° about the x-axis.

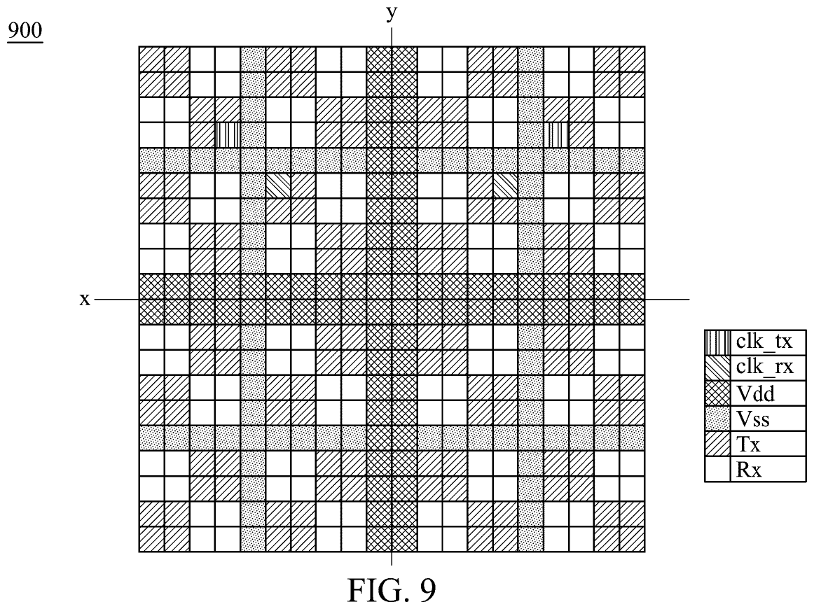

FIG. 9 is a bottom (or top) view illustrating another exemplary interconnects 900 of the semiconductor chip 130 in accordance with various embodiments of the present disclosure. As illustrated in FIG. 9, the example interconnects 900 differ from the interconnects 200-400 in that the interconnects 900 further include transmitter clock (clk_tx) interconnects and receiver clock (clk_rx) interconnects. The chip nodes further includes a transmitter clock (clk_tx) node that transmits a first clock signal and a receiver clock (clk_rx) node that receives a second clock signal. The transmitter clock (clk_tx) interconnects are connected to the transmitter clock (clk_tx) node and are arranged on opposite sides of the y-axis. In this exemplary embodiment, the transmitter clock (clk_tx) interconnects are symmetrical with respect to the y-axis. For example, the number of the transmitter clock (clk_tx) interconnects on one side of the y-axis is the same as the number of the transmitter clock (clk_tx) interconnects on the other side of the y-axis and their positions mirror each other relative to the y-axis.

In an alternative embodiment, the interconnects 900 further include second transmitter clock (clk_tx) interconnects arranged on opposite sides of the y-axis. In such an alternative embodiment, the second transmitter clock (clk_tx) interconnects are asymmetrical with respect to the x-axis. For example, the number of the second transmitter clock (clk_tx) interconnects on one side of the x-axis is greater or less than the number of the second transmitter clock (clk_tx) interconnects on the other side of the x-axis. As another example, the number of the second transmitter clock (clk_tx) interconnects on one side of the x-axis is the same as the number of the transmitter clock (clk_tx) interconnects on the other side of the x-axis. In such another example, the positions of the transmitter clock (clk_tx) interconnects do not form a mirror image with respect to the x-axis.

Similarly, the receiver clock (clk_rx) interconnects are connected to the receiver clock (clk_rx) node and are arranged on opposite sides of the y-axis. In this exemplary embodiment, the receiver clock (clk_rx) interconnects are symmetrical with respect to the y-axis. For example, the number of the receiver clock (clk_rx) interconnects on one side of the y-axis is the same as the number of the receiver clock (clk_rx) interconnects on the other side of the y-axis and their positions mirror each other relative to the y-axis.

In an alternative embodiment, the interconnects 900 further include second receiver clock (clk_rx) interconnects arranged on opposite sides of the x-axis. In such an alternative embodiment, the second receiver clock (clk_rx) interconnects are asymmetrical with respect to the x-axis. For example, the number of the second receiver clock (clk_rx) interconnects on one side of the x-axis is greater or less than the number of the receiver clock (clk_rx) interconnects on the other side of the x-axis. As another example, the number of the second receiver clock (clk_rx) interconnects on one side of the x-axis is the same as the number of the second receiver clock (clk_rx) interconnects on the other side of the x-axis. In such another example, the positions of the second receiver clock (clk_rx) interconnects do not form a mirror image with respect to the y-axis.

From the above description, the semiconductor chip 130 includes interconnects 900 on top and bottom surfaces thereof. The interconnects 900 on the top surface of the semiconductor chip 130 are symmetrical with respect to the y-axis, as are the interconnects 900 on the bottom surface of the semiconductor chip 130. The construction as such ensures correct bonding of the semiconductor chip 130 on another semiconductor chip, e.g., the semiconductor chip 140, or an interposer, e.g., interposer 120, even when the semiconductor chip 130 is rotated by 180°) about the y-axis.

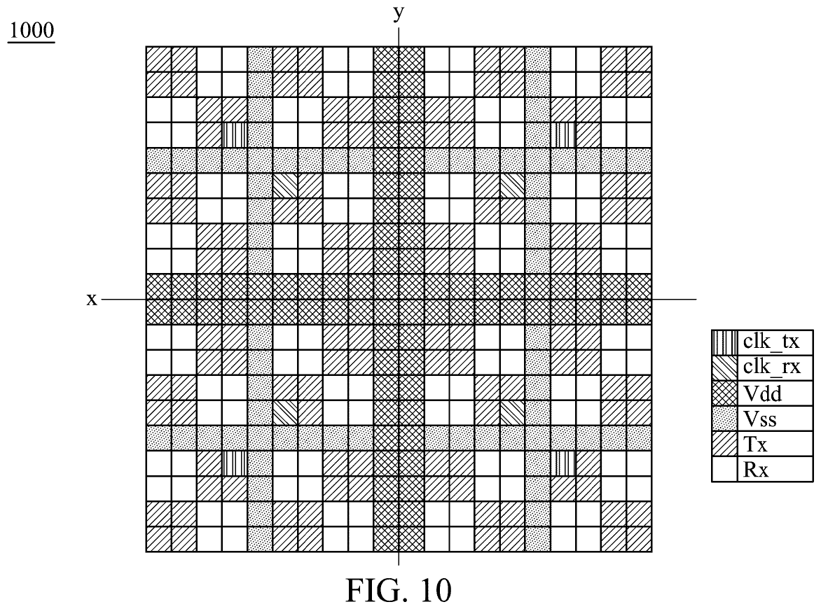

FIG. 10 is a bottom (or top) view illustrating another exemplary interconnects 1000 of the semiconductor chip 130 in accordance with various embodiments of the present disclosure. As illustrated in FIG. 10, the example interconnects 1000 differ from the interconnects 200-400 in that the interconnects 1000 further include transmitter clock (clk_tx) interconnects and receiver clock (clk_rx) interconnects. The chip nodes further includes a transmitter clock (clk_tx) node that transmits a first clock signal and a receiver clock (clk_rx) node that receives a second clock signal. The transmitter clock (clk_tx) interconnects are connected to the transmitter clock (clk_tx) node and are arranged on opposite sides of the x- and y-axes. In this exemplary embodiment, the transmitter clock (clk_tx) interconnects are symmetrical with respect to the x- and y-axes. For example, the number of the transmitter clock (clk_tx) interconnects on one side of the x-axis is the same as the number of the transmitter clock (clk_tx) interconnects on the other side of the x-axis and their positions mirror each other relative to the x-axis. Similarly, the number of the transmitter clock (clk_tx) interconnects on one side of the y-axis is the same as the number of the transmitter clock (clk_tx) interconnects on the other side of the y-axis and their positions mirror each other relative to the y-axis.

In an alternative embodiment, the interconnects 900 further include transmitter clock (clk_tx) interconnects arranged on opposite sides of the x-axis. In such an alternative embodiment, the transmitter clock (clk_tx) interconnects are asymmetrical with respect to the x-axis. For example, the number of the transmitter clock (clk_tx) interconnects on one side of the x-axis is greater or less than the number of the transmitter clock (clk_tx) interconnects on the other side of the x-axis. As another example, the number of the transmitter clock (clk_tx) interconnects on one side of the x-axis is the same as the number of the transmitter clock (clk_tx) interconnects on the other side of the x-axis. In such another example, the positions of the transmitter clock (clk_tx) interconnects do not form a mirror image with respect to the x-axis.

As further illustrated in FIG. 10, the receiver clock (clk_rx) interconnects connected to the receiver clock (clk_rx) node and are arranged on opposite sides of the x- and y-axes. In this exemplary embodiment, the receiver clock (clk_rx) interconnects are symmetrical with respect to the x- and y-axes. For example, the number of the receiver clock (clk_rx) interconnects on one side of the x-axis is the same as the number of the receiver clock (clk_rx) interconnects on the other side of the x-axis and their positions mirror each other relative to the x-axis. Similarly, the number of the receiver clock (clk_rx) interconnects on one side of the y-axis is the same as the number of the receiver clock (clk_rx) interconnects on the other side of the y-axis and their positions mirror each other relative to the y-axis.

From the above description, the semiconductor chip 130 includes interconnects 1000 on top and bottom surfaces thereof. The interconnects 1000 on the top surface of the semiconductor chip 130 are symmetrical with respect to the x- and y-axes, as are the interconnects 1000 on the bottom surface of the semiconductor chip 130. The construction as such ensures correct bonding of the semiconductor chip 130 on another semiconductor chip, e.g., the semiconductor chip 140, or an interposer, e.g., interposer 120, even when the semiconductor chip 130 is rotated by 180° about the x- or y-axis or by 90°, 180°, or 270° about an axis transverse to the x- and y-axes.

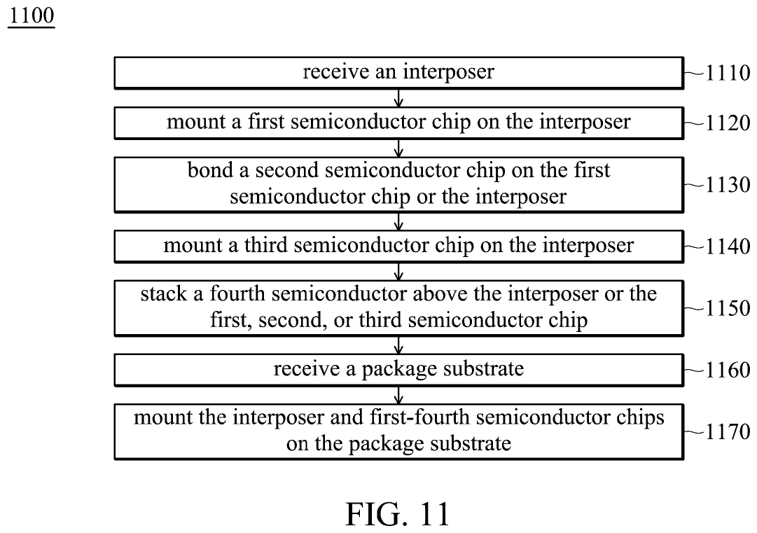

FIG. 11 is a flowchart of an exemplary method 1100 for manufacturing a device with a packaging technology, e.g., a 3D-IC or CoWoS technology, in accordance with various embodiments of the present disclosure. The example method 1100 will now be described with further reference to FIGS. 1-10 for ease of understanding. It is understood that the method 1100 is applicable to structures other than those of FIGS. 1-10. Further, it is understood that additional operations can be provided before, during, and after the method 1100, and some of the operations described below can be replaced or eliminated, in an alternative embodiment of the method 1100.

In operation 1110, the system receives an interposer 120. In operation 1120, the system mounts the semiconductor chip 140 on the interposer 120. In operation 1130, the system bonds the semiconductor chip 130 to the semiconductor chip 140, irrespective of its orientation. In an alternative embodiment, the system bonds the semiconductor chip 130 to the interposer 120.

In this exemplary embodiment, operation 1130 includes: the system receiving a chip substrate 130a; the system forming a device layer 130b on the chip substrate 130a; the system interconnecting chip components of the device layer 130b using a conductive layer 130c; the system defining a plurality of chip nodes (e.g., a supply voltage Vdd node, a supply voltage Vss node, a transmitter Tx node, a receiver Rx node, a transmitter clock clk_tx node, and a receiver clock clk_rx node) connected to conductive layer 130c; forming a plurality of interconnects 130d (e.g., supply voltage Vdd interconnects, supply voltage Vss interconnects, transmitter Tx interconnects, receiver Rx interconnects, transmitter clk_tx interconnects, and a receiver clk_rx interconnects) on the top and bottom surfaces of the conductive layer 130c; and the system covering the chip substrate 130a, the device layer 130b, and the conductive layer 130c with an encapsulant 130e.

In operation 1140, the system mounts the semiconductor chip 150 on the interposer 120. In operation 1150, the system stacks the semiconductor chip 170-180 above the interposer 120 or the semiconductor chip 130, 140, 150. In operation 1160, the system receives a package substrate 110. In operation 1170, the system mounts the stacked interposer 120 and semiconductor chips 130-180 on the package substrate 110.

In an embodiment, a device comprises a plurality of semiconductor chips stacked on top of each other. A semiconductor includes a substrate, a device layer, a conductive layer, a chip node, and a plurality of interconnects. The device layer is formed on the substrate and includes a plurality of chip components. The conductive layer interconnects the chip components. The chip node is connected to the conductive layer and is associated with a distinct signal. The interconnects are formed on a surface of the semiconductor chip, are connected to the chip node, and are arranged symmetrically with respect to an x-axis or a y-axis.

In another embodiment, a device comprises a plurality of semiconductor chips stacked on top of each other. A semiconductor chip includes a substrate, a device layer, a conductive layer, a chip node, and a plurality of interconnects. The device layer is formed on the substrate and includes a plurality of chip components. The conductive layer interconnects the chip components. The chip node is connected to the conductive layer and receives a distinct signal. The interconnects are formed on a surface of the semiconductor chip, are connected to the chip node, and are arranged symmetrically with respect to x- and y-axes.

In another embodiment, a method comprises stacking a plurality of semiconductor chips on top of each other and fabricating a semiconductor chip. Fabricating the semiconductor chip includes: receiving a substrate; forming a device layer on the substrate; interconnecting chip components of the device layer with a conductive layer; defining a chip node connected to the conductive layer and corresponding to a predetermined signal; and connecting a plurality of interconnects to the chip node. The interconnects are arranged symmetrically with respect to an x-axis, a y-axis, or both.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device comprising:
a plurality of semiconductor chips stacked on top of each other, wherein a first semiconductor chip of the plurality of semiconductor chips includes:
a substrate;
a device layer formed on the substrate and including a plurality of chip components;
a conductive layer interconnecting the chip components;
a plurality of chip nodes connected to the conductive layer, wherein each of the chip nodes is associated with a respective one of a plurality of signals; and
a plurality of first interconnects formed on a first surface of the first semiconductor chip, connected to a first chip node of the plurality of chip nodes, and arranged symmetrically with respect to at least one of an x-axis and a y-axis.

2. The device of claim 1, wherein the first interconnects are bonded to a second semiconductor chip of the plurality of semiconductor chips or an interposer or a substrate of the device, establishing electrical connection between the first and second semiconductor chips.

3. The device of claim 1, wherein the first interconnects are symmetrical with respect to the x- or y-axis, ensuring correct bonding of the first semiconductor chip to a second semiconductor chip of the plurality of semiconductor chip even when the first semiconductor chip is rotated by 180° about the x- or y-axis.

4. The device of claim 1, wherein the first interconnects are symmetrical with respect to the x- and y-axes, ensuring correct bonding of the first semiconductor chip to a second semiconductor chip of the plurality of semiconductor chip even when the first semiconductor chip is rotated by 90°, 180°, or 270° about an axis transverse to the x- and y-axes.

5. The device of claim 1, further comprising a plurality of second interconnects formed on a second surface of the first semiconductor chip, connected to the first chip node, and arranged symmetrically with respect to the x- or y-axis.

6. The device of claim 1, further comprising a substrate, wherein the first semiconductor chip is bonded to the substrate.

7. The device of claim 1, further comprising an interposer, wherein the first semiconductor chip is bonded to the interposer.

8. A device comprising:
a plurality of semiconductor chips stacked on top of each other, wherein a first semiconductor chip of the plurality of semiconductor chips includes:
a substrate;
a device layer formed on the substrate and including a plurality of chip components;
a conductive layer interconnecting the chip components;
a plurality of chip nodes connected to the conductive layer, wherein each of the chip nodes is configured to receive a respective one of a plurality of signals; and
a plurality of first interconnects formed on a first surface of the first semiconductor chip, connected to a first chip node of the plurality of the chip nodes, and arranged symmetrically with respect to x- and y-axes.

9. The device of claim 8, wherein the chip node is configured to receive a data signal transmitted by the first semiconductor chip, a data signal transmitted by a second semiconductor chip of the plurality of semiconductor chips, a VSS signal, or a VDD signal.

10. The device of claim 8, further comprising a plurality of second interconnects formed on a second surface of the first semiconductor chip, connected to the first chip node, and arranged symmetrically with respect to the x- and y-axes.

11. The device of claim 8, further comprising an interposer, wherein the first semiconductor chip is bonded to the interposer.

12. The device of claim 8, wherein the first semiconductor chip is bonded to a second semiconductor chip of the plurality of semiconductor chip.

13. A method comprising:
stacking a plurality of semiconductor chips on top of each other; and
fabricating a semiconductor chip by:
receiving a substrate;
forming a device layer on the substrate;
interconnecting chip components of the device layer with a conductive layer;
defining a first chip node connected to the conductive layer and corresponding to a first predetermined signal; and
connecting a plurality of first interconnects to the first chip node, wherein the first interconnects are arranged symmetrically with respect to an x-axis, a y-axis, or both.

14. The method of claim 13, wherein the first interconnects are symmetrical with respect to the x- or y-axis, ensuring correct bonding of the first semiconductor chip to a second semiconductor chip of the plurality of semiconductor chip even when the first semiconductor chip is rotated by 180° about the x- or y-axis.

15. The device of claim 13, wherein the first interconnects are symmetrical with respect to the x- and y-axes, ensuring correct bonding of the first semiconductor chip to a second semiconductor chip of the plurality of semiconductor chip even when the first semiconductor chip is rotated by 90°, 180°, or 270° about an axis transverse to the x- and y-axes.

16. The method of claim 13, wherein the predetermined signal is transmitted by the device layer, received from another semiconductor chip, a VDD signal, or a VSS signal.

17. The method of claim 13, further comprising:
defining a second chip node connected to the conductive layer and corresponding to a second predetermined signal; and
connecting a plurality of second interconnects to the second chip node, wherein the second interconnects are arranged symmetrically with respect to the x- or y-axis or both.

18. The method of claim 17, wherein the second predetermined signal is transmitted by the device layer, received from another semiconductor chip, a VDD signal, or a VSS signal.

19. The method of claim 13, further comprising:
forming the first interconnects on a bottom surface of the semiconductor chip;
connecting a plurality of second interconnects to the first chip node; and
forming the second interconnects on a top surface of the semiconductor chip.

20. The method of claim 13, further comprising covering the substrate and the device layer with an encapsulant.
